(19) United States
(12) Patent Application Publication
(10) Pub. No.: US 2025/0191927 A1
(43) Pub. Date: Jun. 12, 2025

(54) ETCHING METHOD AND PLASMA PROCESSING SYSTEM

(71) Applicant: Tokyo Electron Limited, Tokyo (JP)

(72) Inventors: Takuya SAWANO, Miyagi (JP); Masahito YAMAGUCHI, Miyagi (JP); Maju TOMURA, Miyagi (JP); Yoshihide KIHARA, Miyagi (JP)

(73) Assignee: Tokyo Electron Limited, Tokyo (JP)

(21) Appl. No.: 19/059,516

(22) Filed: Feb. 21, 2025

Related U.S. Application Data
(63) Continuation of application No. PCT/JP2023/028958, filed on Aug. 8, 2023.

(30) Foreign Application Priority Data
Aug. 22, 2022 (JP) 2022-131695

(51) Int. Cl. H01L 21/311

(52) U.S. Cl. CPC H01L 21/31116; H01L 21/31144

(57) ABSTRACT

An etching method is provided. The method comprises: (a) preparing a substrate on a substrate support within a chamber, the substrate comprising a silicon-containing film having a first recess and a second recess with a smaller opening dimension than the first recess, and a mask formed on the silicon-containing film, the mask having openings that expose the first recess and the second recess; (b) forming a deposition film at least in the first recess using plasma generated from a first processing gas, wherein the first processing gas includes at least one gas selected from a group consisting of C₃F₆, C₄F₆, C₄F₈, isopropyl alcohol (IPA) gas, C₃H₂F₄, and C₄H₂F₆; and (c) etching the silicon-containing film in the first recess and the second recess using plasma generated from a second processing gas.

### CROSS-REFERENCE TO RELATED APPLICATIONS

This application is a bypass continuation application of International Application No. PCT/JP2023/028958 having an international filing date of Aug. 8, 2023, and designating the United States, the International Application being based upon and claiming the benefit of priority from Japanese Patent Application No. 2022-131695 filed on Aug. 22, 2022, the entire contents of each are incorporated herein by reference.

### TECHNICAL FIELD

The exemplary embodiment of the present disclosure relates to an etching method and a plasma processing system.

### BACKGROUND

Japanese Laid-open Patent Publication No. 2000-150632 discloses forming trenches with different depths on a semiconductor substrate using masks with varying aperture dimensions.

### SUMMARY

The present disclosure provides a technique for etching a region having different aperture dimensions.

In one exemplary embodiment of the present disclosure, an etching method performed by a plasma processing apparatus having a chamber is provided. The method comprises: (a) preparing a substrate on a substrate support within the chamber, the substrate comprising a silicon-containing film having a first recess and a second recess with a smaller opening dimension than the first recess, and a mask formed on the silicon-containing film, the mask having openings that expose the first recess and the second recess; (b) forming a deposition film at least in the first recess using plasma generated from a first processing gas within the chamber, wherein the first processing gas includes at least one gas selected from a group consisting of C₃F₆ gas, C₄F₆ gas, C₄F₈ gas, isopropyl alcohol (IPA) gas, C₃H₂F₄ gas, and C₄H₂F₆ gas; and (c) etching the silicon-containing film in the first recess and the second recess using plasma generated from a second processing gas within the chamber. In process (b), the temperature of the substrate support is set to 0° C. or lower, and a pressure within the chamber is set to be higher than a pressure within the chamber in process (c).

### BRIEF DESCRIPTION OF THE DRAWINGS

FIG. 1 is a schematic view an exemplary plasma processing system.

FIG. 2 is a flowchart illustrating an embodiment of the present processing method.

FIG. 3 illustrates an example of a cross-sectional structure of substrate W provided by the process ST11.

FIG. 4 illustrates an example of a cross-sectional structure of substrate W

FIG. 5A illustrates an example of a cross-sectional structure of substrate W after processing of the process ST2.

FIG. 5B illustrates another example of a cross-sectional structure of substrate W after processing of the process ST2.

FIG. 6 illustrates an example of a cross-sectional structure of substrate W after processing of process ST3.

FIG. 7 is a flowchart illustrating another embodiment of the present processing method.

### DETAILED DESCRIPTION

Hereinafter, each embodiment of the present disclosure will be described.

In one exemplary embodiment, an etching method performed by a plasma processing apparatus having a chamber is provided. The method comprises: (a) preparing a substrate on a substrate support within the chamber, the substrate comprising a silicon-containing film having a first recess and a second recess with a smaller opening dimension than the first recess, and a mask formed on the silicon-containing film, the mask having openings that expose the first recess and the second recess; (b) forming a deposition film at least in the first recess using plasma generated from a first processing gas within the chamber, wherein the first processing gas includes at least one gas selected from a group consisting of C₃F₆ gas, C₄F₆ gas, C₄F₈ gas, isopropyl alcohol (IPA) gas, C₃H₂F₄ gas, and C₄H₂F₆ gas; and (c) etching the silicon-containing film in the first recess and the second recess using plasma generated from a second processing gas within the chamber. In process (b), the temperature of the substrate support is set to 0° C. or lower, and a pressure within the chamber is set to be higher than a pressure within the chamber in process (c).

In one exemplary embodiment, an etching method performed by a plasma processing apparatus having a chamber is provided. The method comprises: (a) preparing a substrate on a substrate support within the chamber, the substrate comprising a silicon-containing film having a first recess and a second recess with a smaller opening dimension than the first recess, and a mask formed on the silicon-containing film, the mask having openings that expose the first recess and the second recess; (b) forming a deposition film at least in the first recess using plasma generated from a first processing gas within the chamber, wherein the first processing gas includes a gas that exhibits vapor pressure at a temperature equal to or higher than the temperature indicated by the temperature-vapor pressure curve of C₄F₈; and (c) etching the silicon-containing film in the first recess and the second recess using plasma generated from a second processing gas within the chamber. In process (b), the temperature of the substrate support is set to 0° C. or lower, and the pressure within the chamber is set to be higher than the pressure within the chamber in process (c).

In one exemplary embodiment, the depth of the first recess in the substrate prepared in process (a) is greater than the depth of the second recess.

In one exemplary embodiment, in process (b), the deposition film is formed at least on the bottom of the first recess.

In one exemplary embodiment, in process (b), the deposition film is formed on the first recess and the second recess, and when process (b) is terminated, the thickness of the deposition film formed in the first recess, measured from the top to the bottom, is thicker than the thickness of the deposition film formed on the second recess, measured from the top to the bottom.

In one exemplary embodiment, when process (b) is terminated, a lower part of the deposition film formed in the first recess is located at a position deeper than that of a lower part of the deposition film formed in the second recess.

In one exemplary embodiment, process (b) and process (c) are alternately repeated.

In one exemplary embodiment, process (b) and process (c) are performed within the same chamber.

In one exemplary embodiment, in process (b), the pressure within the chamber is 50 mT (6.7 Pa) or more.

In one exemplary embodiment, in process (b), no bias signal is supplied to the substrate support, or a bias signal is supplied at a lower level than the bias signal in process (c).

In one exemplary embodiment, the second processing gas includes a fluorine-containing gas.

In one exemplary embodiment, the fluorine-containing gas includes at least one of hydrogen fluoride gas and hydrofluorocarbon gas.

In one exemplary embodiment, in process (c), temperature of the substrate support is set to 0° C. or lower.

In one exemplary embodiment, the second processing gas further includes at least one of a phosphorus-containing gas and a carbon-containing gas.

In one exemplary embodiment, the second processing gas further includes at least one gas selected from a group consisting of a tungsten-containing gas, a halogen-containing gas other than fluorine, an oxygen-containing gas, and an inert gas.

In one exemplary embodiment, in process (c), plasma generated from the second processing gas includes at least one of HF species, phosphorus-containing species, and carbon-containing species.

In one exemplary embodiment, process (a) includes a step of forming the first recess and the second recess by etching using plasma generated from the second processing gas.

In one exemplary embodiment, the silicon-containing film is a laminated film that includes a silicon oxide film, a silicon nitride film, a silicon oxynitride film, a silicon carbonitride film, a polysilicon film, a carbon-containing silicon film, or a combination of two or more of the above.

In one exemplary embodiment, the mask includes at least one of carbon, tungsten, titanium, and molybdenum.

In one exemplary embodiment, a plasma processing system equipped with a plasma processing apparatus with a chamber and a controller is provided. The controller is configured to perform controlling of: (a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess; (b) forming a deposition film on at least the first recess using plasma generated from a first processing gas within the chamber, wherein the first processing gas includes at least one gas selected from a group consisting of C₃F₆ gas, C₄F₆ gas, C₄F₈ gas, isopropyl alcohol (IPA) gas, C₃H₂F₄ gas, and C₄H₂F₆ gas; and (c) etching the silicon-containing film in the first recess and the second recess using plasma generated from a second processing gas within the chamber. The temperature of the substrate support is set to 0° C. or lower in the controlling of (b), while the pressure within the chamber is higher than the pressure within the chamber in the controlling of (c).

In what follows, each embodiment of the present disclosure will be described in detail with reference to appended drawings. Also, the same or similar constituting elements in the respective drawings are given the same reference number irrespective of their drawing symbols, and repeated descriptions thereof will be omitted. Unless otherwise specified, positional relationships such as up, down, left, and right are described based on the positional relationships shown in the drawings. The dimensional ratios in the drawings do not represent actual ratios, nor are the actual ratios limited to the ratios illustrated in the drawings.

### <An Example of the Configuration of a Plasma Processing System>

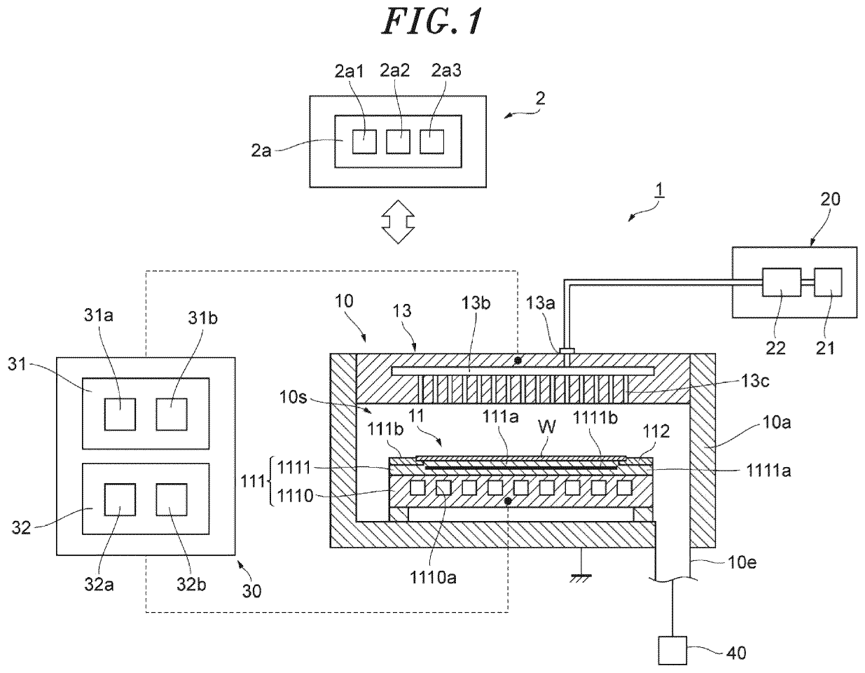

In what follows, an example of the configuration of a plasma processing system will be described. FIG. 1 illustrates an example of the configuration of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply 20, a power supply 30, and an exhaust system 40. The plasma processing apparatus 1 also includes a substrate support 11 and a gas introduction unit. The gas introduction unit is configured to introduce at least one processing gas into the plasma processing chamber 10. The gas introduction unit includes a showerhead 13. The substrate support 11 is disposed in the plasma processing chamber 10. The showerhead 13 is disposed above the substrate support 11. In one embodiment, the showerhead 13 forms at least a portion of the ceiling of the plasma processing chamber 10. The plasma processing chamber 10 has the plasma processing space 10s defined by the showerhead 13, a sidewall 10a of the plasma processing chamber 10, and the substrate support 11. The plasma processing chamber 10 includes at least one gas inlet for supplying at least one processing gas to the plasma processing space 10s and at least one gas outlet for discharging gas from the plasma processing space. The plasma processing chamber 10 is grounded. The showerhead 13 and the substrate support 11 are electrically insulated from the housing of the plasma processing chamber 10.

The substrate support 11 includes a main body 111 and a ring assembly 112. The main body 111 includes a central region 111a for supporting the substrate W and an annular region 111b for supporting the ring assembly 112. A wafer is an example of the substrate W. The annular region 111b of the main body 111 surrounds the central region 111a of the main body 111 when projected onto a plane. The substrate W is disposed on the central region 111 of the main body 111, and the ring assembly 112 is disposed on the annular region 111b of the main body to surround the substrate W on the central region 111a. Therefore, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 contains a conductive member. The conductive member of the base 1110 may function as a lower electrode. The electrostatic chuck 1111 is disposed on top of the base 1110. The electrostatic chuck 1111 includes a ceramic member 1111a and an electrostatic electrode 1111b disposed within the ceramic member 1111a. The ceramic member 1111a has a central region 111a. In one embodiment, the ceramic member 1111a also includes an annular region 111b. Also, other members surrounding the electrostatic chuck 1111, such as an annular electrostatic chuck or an annular insulating member, may include the annular region 111b. In this case, the ring assembly 112 may be disposed on top of the annular electrostatic chuck, the annular insulating member, or both the electrostatic chuck 1111 and the annular insulating member. Moreover, at least one RF/DC electrode, coupled to the Radio Frequency (RF) power supply 31 and/or the Direct Current (DC) power supply 32, may be disposed within the ceramic member 1111a. In this case, at least one RF/DC electrode functions as a lower electrode. When a bias RF signal and/or DC signal, described later, is supplied to at least one RF/DC electrode, the RF/DC electrode is also referred to as a bias electrode. Also, the conductive member of the base 1110 and at least one RF/DC electrode may function as a plurality of lower electrodes. The electrostatic electrode 1111b may also function as a lower electrode. Therefore, the substrate support 11 includes at least one lower electrode.

The ring assembly 112 includes one or more annular members. In one embodiment, the one or more annular members comprise one or more edge rings and at least one cover ring. The edge ring is formed of a conductive or insulating material, while the cover ring is formed of an insulating material.

Also, the substrate support 11 may include a temperature control module configured to adjust the temperature of at least one of the electrostatic chuck 1111, the ring assembly 112, and the substrate to a target temperature. The temperature control module may include a heater, a heat transfer medium, a flow channel 1110a, or a combination thereof. A heat transfer fluid, such as brine or gas, flows through the flow channel 1110a. In one embodiment, the flow channel 1110a is formed within the base 1110, and one or more heaters are disposed within the ceramic member 1111a of the electrostatic chuck 1111. Also, the substrate support 11 may include a heat transfer gas supply configured to supply heat transfer gas into the gap between the back side of the substrate W and the central region 111a.

The showerhead 13 is configured to introduce at least one processing gas from the gas supply 20 into the plasma processing space 10s. The showerhead 13 has at least one gas supply port 13a, at least one gas diffusion chamber 13b, and a plurality of gas inlets 13c. The processing gas supplied to the gas supply port 13a passes through the gas diffusion chamber 13b and is introduced into the plasma processing space 10s from the plurality of gas inlets 13c. Also, the showerhead 13 includes at least one upper electrode. Furthermore, the gas introduction unit may include, in addition to the showerhead 13, one or more side gas injectors (SGI) provided in one or more openings formed in the sidewall 10a.

The gas supply 20 may include at least one gas source 21 and at least one flow controller 22. In one embodiment, the gas supply 20 is configured to supply at least one processing gas from the corresponding gas source 21 through the corresponding flow controller 22 to the showerhead 13. Each flow controller 22 may include, for example, a mass flow controller or a pressure-controlled flow controller. Also, the gas supply 20 may include one or more flow modulation devices for modulating or pulsing the flow rate of at least one processing gas.

The power supply 30 includes an RF power supply 31 that is coupled to the plasma processing chamber 10 through at least one impedance matching circuit. The RF power supply 31 is configured to supply at least one RF signal (RF power) to at least one lower electrode and/or at least one upper electrode. Thus, plasma is formed from at least one processing gas supplied to the plasma processing space 10s. Therefore, the RF power supply 31 may function as at least a portion of a plasma generator configured to generate plasma from one or more processing gases in the plasma processing chamber 10. Furthermore, by supplying a bias RF signal to at least one lower electrode, a bias potential may be generated on the substrate W, and ion components in the formed plasma may be drawn into the substrate W.

In one embodiment, the RF power supply 31 includes a first RF generator 31a and a second RF generator 31b. The first RF generator 31a is coupled to at least one lower electrode and/or at least one upper electrode via at least one impedance matching circuit and is configured to generate the source RF signal (source RF power) for plasma generation. In one embodiment, the source RF signal has a frequency in the range of 10 MHz to 150 MHz. In one embodiment, the first RF generator 31a may be configured to generate multiple source RF signals having different frequencies. The generated source RF signal or signals are supplied to at least one lower electrode and/or at least one upper electrode.

The second RF generator 31b is coupled to at least one lower electrode via at least one impedance matching circuit and is configured to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in the range of 100 KHz to 60 MHz. In one embodiment, the second RF generator 31b may be configured to generate multiple bias RF signals having different frequencies. The generated bias RF signal or signals are supplied to at least one lower electrode. In various embodiments, at least one of the source RF signal and the bias RF signal may be pulsed.

The power supply 30 may also include a DC power supply 32 coupled to the plasma processing chamber 10. The DC power supply 32 includes a first DC generator 32a and a second DC generator 32b. In one embodiment, the first DC generator 32a is configured to be connected to at least one lower electrode and to generate a first DC signal. The generated first bias DC signal is applied to at least one lower electrode. In one embodiment, the second DC generator 32b is configured to be coupled to at least one upper electrode and to generate a second DC signal. The generated second DC signal is applied to at least one upper electrode.

In various embodiments, at least one of the first and second DC signals may be pulsed. In this case, a sequence of voltage pulses is applied to at least one lower electrode and/or at least one upper electrode. The voltage pulses may have a pulse waveform such as rectangular, trapezoidal, triangular, or a combination of the waveforms. In one embodiment, a waveform generator for generating a sequence of voltage pulses from a DC signal is connected between the first DC generator 32a and at least one lower electrode. Accordingly, the first DC generator 32a and the waveform generator constitute a voltage pulse generator. When the second DC generator 32b and the waveform generator constitute the voltage pulse generator, the voltage pulse generator is connected to at least one upper electrode. The voltage pulses may have positive polarity or negative polarity. Also, the sequence of voltage pulses may include one or more positive voltage pulses and one or more negative voltage pulses within a single cycle. Furthermore, the first and second DC generators 32a and 32b may be additionally provided to the RF power supply 31, or the first DC generator 32a may be provided in place of the second RF generator 31b.

The exhaust system 40 may be connected to a gas discharge port 10e provided on a bottom of the plasma processing chamber 10, for example. The exhaust system 40 may include a pressure control valve and a vacuum pump. The pressure within the plasma processing space 10s is adjusted by the pressure control valve. The vacuum pump may include a turbo molecular pump, a dry pump, or a combination thereof.

The controller 2 processes computer-executable instructions to perform various processes described in the present disclosure on the plasma processing apparatus 1. The controller 2 may be configured to control each component of the plasma processing apparatus 1 to execute the processes described in the present disclosure. In one embodiment, all or part of the controller 2 may be included within the plasma processing apparatus 1. The controller 2 may include a processor 2a1, a memory unit 2a2, and a communication interface 2a3. The controller 2 may, for example, be implemented by a computer 2a. The processor 2a1 may be configured to read programs from the memory unit 2a2 and execute various control operations by executing the read programs. These programs may be pre-stored in the memory unit 2a2 or acquired as needed through a medium. The acquired programs may be stored in the memory unit 2a2 and executed after being read from the memory unit 2a2 by the processor 2a1. The medium may include various storage media readable by the computer 2a or communication lines connected to the communication interface 2a3. The processor 2a1 may be a Central Processing Unit (CPU). The memory unit 2a2 may include a Random Access Memory (RAM), a Read Only Memory (ROM), a Hard Disk Drive (HDD), a Solid State Drive (SSD), or a combination thereof. The communication interface 2a3 may communicate with the plasma processing apparatus 1 via communication lines such as a Local Area Network (LAN).

### <An Example of a Plasma Processing Method>

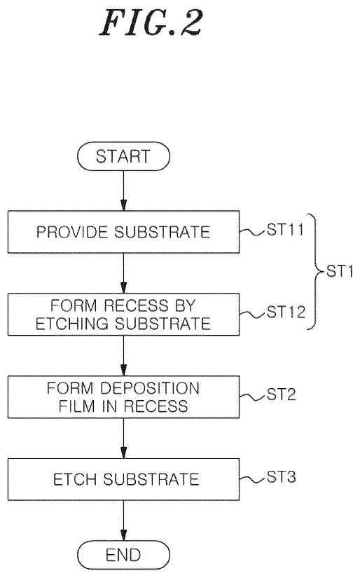

FIG. 2 is a flowchart illustrating an example of a plasma processing method (hereinafter also referred to as “the present processing method”) according to an exemplary embodiment. As shown in FIG. 2, the present processing method includes a process ST1 of preparing a substrate, a process ST2 of forming a deposition film in a recess, and a process ST3 of etching the recess. The processing steps in each process may be executed in the plasma processing system shown in FIG. 1. In what follows, a case is described as an example in which the controller 2 controls each part of the plasma processing apparatus 1 to execute the present processing method on the substrate W. Also, the processing steps in ST1 to ST3 processes do not necessarily need to be executed in the same plasma processing chamber 10. For example, process ST2 and process ST3 may be executed in different plasma processing chambers.

### (Process ST1: Preparation of Substrates)

As shown in FIG. 2, process ST1 includes a process ST11 of providing the substrate W and a process of etching the substrate W to form a recess. First, in process ST11, the substrate W is provided within the plasma processing space 10s of the plasma processing apparatus 1. The substrate W is placed on the central region 111a of the substrate support 11. Subsequently, the substrate W is held on the substrate support 11 by the electrostatic chuck 1111.

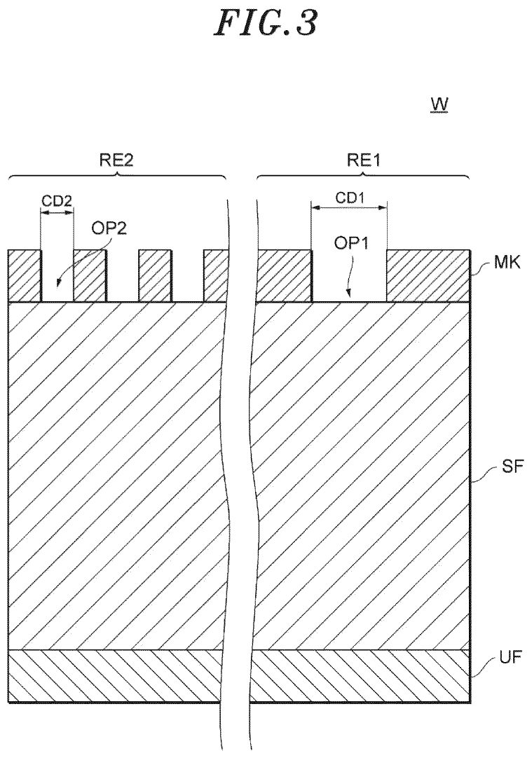

FIG. 3 illustrates an example of the cross-sectional structure of substrate W provided during process ST11. As shown in FIG. 3, substrate W includes a base film UF, a silicon-containing film SF, and a mask MK. The substrate W may be used in the manufacture of semiconductor devices. Semiconductor devices include, for example, semiconductor memory devices such as DRAM and 3D-NAND flash memory.

Substrate W includes a first region RE1 and a second region RE2. When viewed in the plane of substrate W (as seen from the top surface in FIG. 3), regions RE1 and RE2 each occupy a defined area on substrate W. The first region RE1 and the second region RE2 may be adjacent to one another or separated from each other. The first region RE1, for example, may correspond to an area where structures such as through-hole vias or slits are formed in a semiconductor memory device. The second region RE2, for example, may correspond to an area where contact plugs or multi-level contacts are formed in a semiconductor memory device.

The base film UF extends from the first region RE1 to the second region RE2. The base film UF may comprise, for example, a silicon wafer or an organic film, dielectric film, metal film, or semiconductor film formed on the silicon wafer. The base film UF may either be a single-layer film or a multilayer film consisting of stacked/laminated films. In one example, the base film UF is a polysilicon film or a metal-containing film, such as tungsten.

The silicon-containing film SF is formed on the base film UF, extending from the first region RE1 to the second region RE2. The silicon-containing film SF serves as the target film for etching according to the present processing method. The silicon-containing film SF may include, for example, a silicon oxide film, a silicon nitride film, a silicon oxynitride film, a silicon carbonitride film, a polysilicon film, or a carbon-containing silicon film. The silicon-containing film SF may also be configured as a multilayer structure with multiple films stacked together. For example, the silicon-containing film SF may be structured with alternating layers of silicon oxide and silicon nitride films. For example, the silicon-containing film SF may be composed of alternating layers of silicon oxide and polysilicon films. For example, the silicon-containing film SF may include a multilayer structure containing silicon nitride, silicon oxide, and polysilicon films. For example, the silicon-containing film SF may be composed of stacked/laminated layers of silicon oxide and silicon carbonitride films. The silicon-containing film SF may be a multilayer film comprising silicon oxide, silicon nitride, and silicon carbonitride films.

The silicon-containing film SF in the first region RE1 and the silicon-containing film SF in the second region RE2 may be composed of the same type of films or different types of films. In one example, the silicon-containing film SF in both the first region RE1 and the second region RE2 consists of a single-layer silicon oxide film. In another embodiment, the silicon-containing film SF in both the first region RE1 and the second region RE2 consists of a multilayer film formed by alternating layers of silicon nitride and silicon oxide films. In yet another example, the silicon-containing film SF in the first region RE1 consists of a single-layer silicon oxide film, while the silicon-containing film SF in the second region RE2 consists of a multilayer film with alternating layers of silicon nitride and silicon oxide films.

The mask MK is provided on the silicon-containing film SF, extending from the first region RE1 to the second region RE2. The mask MK has a predefined pattern. In the first region RE1, the mask MK includes one or more openings OP1. Also, in the second region RE2, the mask MK includes one or more openings OP2. For example, the openings OP1 and OP2 are defined by the sidewalls formed in the mask MK.

The openings OP1 and OP2 are, in one example, openings formed in the silicon-containing film SF to form holes, contact holes, line-and-space patterns, slits, trenches, or similar structures. In one example, the openings OP1 and OP2, when projected onto a plane, may have shapes such as circular, elliptical, linear, or rectangular shape. The shapes of OP1 and OP2, when projected onto a plane, may be similar or different. As shown in FIG. 3, the opening dimension CD1 of OP1 (e.g., the diameter of a circular opening, the minor axis of an elliptical opening, the width of a linear opening, or the length of a short or long side of a rectangular opening) is larger than the opening dimension CD2 of OP2.

The mask MK is formed of a material with a lower etching rate against the plasma generated in the process ST12 compared to that of the silicon-containing film SF. The mask MK may be formed, for example, of a carbon-containing material. In one example, the mask MK is an amorphous carbon film, a photoresist film, or a Spin-On Carbon (SOC) film. For example, the mask MK may be a metal-containing film including at least one metal selected from a group consisting of tungsten, molybdenum, and titanium. In one example, the mask MK includes tungsten carbide or tungsten silicide. The mask MK may be a single-layer mask composed of one layer or a multi-layer mask composed of two or more layers.

Each film constituting the substrate W (the base film UF, the silicon-containing film SF, or the mask MK) may be formed using methods such as CVD, ALD, or spin coating. The mask MK may also be formed through lithography. Furthermore, the opening OP of the mask MK may be created by etching the mask MK. Each film may be either a flat film or a film with uneven surfaces. Also, the substrate W may include another film beneath the base film UF. In this case, a recess corresponding to the shape of the opening OP may be formed in the silicon-containing film SF and the base film UF, and the recess may serve as a mask for etching the corresponding additional layer.

At least part of the process for forming each film of the substrate W may be carried out within the space of the plasma processing chamber 10. In one example, the process of etching the mask MK to form the opening OP may be performed in the plasma processing chamber 10. In other words, the etching of the opening OP and the silicon-containing film SF in the process ST12 described later may be executed consecutively within the same chamber. Furthermore, after all the films of the substrate W are formed in an external device or a chamber outside the plasma processing apparatus 1, the substrate W may be brought into the plasma processing space 10s of the plasma processing apparatus 1 and disposed in the central region 111a of the substrate support 11, which may provide the substrate W.

After the substrate W is provided to the central region 111a of the substrate support 11, the temperature of the substrate support 11 is adjusted to a set temperature by the temperature controller. The set temperature may be, for example, a temperature of 70° C. or lower (e.g., room temperature). Also, for example, the set temperature may be 0° C. or lower, −10° C. or lower, −20° C. or lower, −30° C. or lower, −40° C. or lower, −50° C. or lower, −60° C. or lower, or −70° C. or lower. In one example, adjusting or maintaining the temperature of the substrate support 11 involves setting the temperature of the heat transfer fluid flowing through the flow path 1110a or the temperature of a heater to the set temperature or setting the temperature to a temperature different from the set temperature. Also, the timing at which the heat transfer fluid begins to flow through the flow path 1110a may be before, after, or simultaneously with the placement of the substrate W on the substrate support 11. Also, the temperature of the substrate support 11 may be adjusted to the set temperature before the process ST11. In other words, the substrate W may be provided to the substrate support 11 after the temperature of the substrate support 11 is adjusted to the set temperature.

Next, in the process ST12, the silicon-containing film SF is etched using plasma generated from the processing gas. The processing gas may be selected such that the silicon-containing film SF may be etched with a sufficiently high selectivity relative to the mask MK. The processing gas may be the same as or different from the second processing gas used in the etching step of the process ST3, which will be described later.

First, the processing gas is supplied into the plasma processing space 10s from the gas supply 20. During the process ST12, the type of gas included in the processing gas or its flow rate (partial pressure) may or may not be modified. For example, if the silicon-containing film SF is composed of a multilayer film made of different types of silicon-containing films, the composition of the processing gas or the flow rate (partial pressure) of each gas may be adjusted as the etching progresses (i.e., depending on the type of film being etched). During the process ST12, the temperature of the substrate support 11 may be maintained at the set temperature adjusted in the process ST11. Also, the set temperature of the substrate support 11 may be changed depending on the type of processing gas or silicon-containing film. For example, when the processing gas includes a fluorine-containing gas (e.g., hydrogen fluoride gas), the set temperature of the substrate support 11 may be 0° C. or lower. In the process ST12, the pressure in the plasma processing space 10s may be lower than the pressure in the plasma processing space 10s during the process ST2 described later. The pressure, for example, may be less than 50 mT (6.7 Pa).

Next, a source RF signal is supplied to the lower electrode of the substrate support 11 and/or the upper electrode of the showerhead 13. This creates a high-frequency electric field between the showerhead 13 and the substrate support 11, generating plasma from the processing gas within the plasma processing space 10s. Also, a bias signal is supplied to the lower electrode of the substrate support 11, creating a bias potential between the plasma and the substrate W. Due to the bias potential, reactive species in the plasma, such as ions and radicals, are drawn toward the substrate W. As a result, the exposed portion of the silicon-containing film SF that are not covered by the mask MK (e.g., the areas exposed in openings OP1 and OP2) are etched, forming a recess. When a specified termination condition is met, the etching process stops, and the process ST21 is terminated. The termination condition may be, for example, the etching time or the depth of a created recess.

In the process ST12, the bias signal may be a bias RF signal supplied from the second RF generator 31b. Also, the bias signal may be a bias DC signal supplied from the DC generator 32a. Both the source RF signal and the bias signal may be continuous waves or pulsed waves, or one may be a continuous wave while the other is a pulsed wave. If both the source RF signal and the bias signal are pulsed waves, the periods of the pulsed waves may or may not be synchronized. The duty ratio of the source RF signal and/or bias signal may be set appropriately; for example, the duty ratio may range from 1% to 80% or 5% to 50%. The duty ratio refers to the proportion of time within the period of a pulsed wave during which the power or voltage level remains high. Also, if the bias DC signal is used as the bias signal, the pulsed wave may have a waveform such as rectangular, trapezoidal, triangular, or a combination of the aforementioned waves. The polarity of the bias DC signal may be negative or positive, depending on the potential set for the substrate W to create a potential difference between the plasma and the substrate for attracting ions.

In the process ST12, the supply and cessation of at least one of the source RF signal and the bias signal may be repeated in an alternate fashion. For example, while the source RF signal is supplied continuously, the supply and cessation of the bias signal may be repeated alternately. Alternatively, while the supply and cessation of the source RF signal is repeated alternately, the bias signal may be supplied continuously. Furthermore, the supply and cessation of both the source RF signal and the bias signal may be repeated alternately.

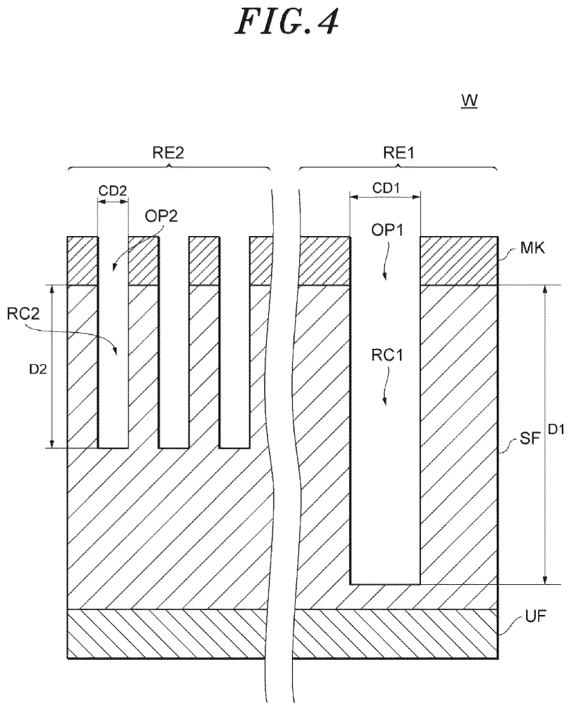

FIG. 4 illustrates an example of the cross-sectional structure of substrate W after processing of the process ST12. As shown in FIG. 4, during the etching step of the process ST12, the exposed portions of the silicon-containing film SF at openings OP1 and OP2 are etched in the depth direction (downward direction in FIG. 4). In the first region RE1 of substrate W, a first recess RC1 with a shape corresponding to opening OP1 is formed. Also, in the second region RE2 of substrate W, a second recess RC2 with a shape corresponding to opening OP2 is formed. The opening dimension CD1 of the first recess RC1 is larger than the opening dimension CD2 of the second recess RC2. The depth D1 of the first recess RC1 may be greater than the depth D2 of the second recess RC2. In other words, the etching rate of the silicon-containing film SF in the region RE1 during the process ST12 may be higher than that in the region RE2. This difference may be considered to result from the fact that the opening dimension CD1 of the mask MK in the region RE1 is larger than the opening dimension CD2 of mask MK in the region RE2. It is so because the incidence frequency of reactive species in the plasma to the first recess RC1 may be higher compared to that to the second recess RC2.

FIG. 4 illustrates an example in which (a stop condition is set for terminating) the process ST12 is terminated before the bottom of the first recess RC1 reaches the base film UF. Alternatively, the etching step of the process ST12 may be terminated (or a stop condition may be set to terminate the etching step) just before the first recess RC1 reaches the base film UF or at a stage where all or part of the base film UF is exposed.

As described above, in the process ST1, a substrate is prepared on the substrate support 11 of the plasma processing chamber 10, where the substrate includes a silicon-containing film SF with a first recess RC1 and a second recess RC2 having a smaller opening dimension than the first recess RC1 and a mask MK formed on the silicon-containing film SF and with openings OP1 and OP2 that expose the first recess RC1 and the second recess RC2. In the aforementioned example, the substrate W is prepared by providing the substrate W on the substrate support 11 (process ST11) and etching the corresponding substrate W to form recesses in the silicon-containing film SF (process ST12). However, the substrate W may also be prepared in such a way that, after the recesses are formed on the substrate W using a device or a chamber external to the plasma processing apparatus 1, the substrate W in which the recesses have been formed is provided on the substrate support 11 of the plasma processing apparatus 1.

### (Process ST2: Forming a Deposition Film in the Recess)

In the process ST2, a deposition film is formed in the first recess RC1 of the silicon-containing film SF. First, the first processing gas is supplied into the plasma processing space 10s from the gas supply 20. Next, a source RF signal is supplied to the lower electrode of the substrate support 11 and/or the upper electrode of the showerhead 13. As a result, a high-frequency electric field is generated between the showerhead 13 and the substrate support 11, leading to the generation of plasma from the first processing gas in the plasma processing space 10s. A bias signal may or may not be supplied to the lower electrode of the substrate support 11. If a bias signal is supplied, the level of the bias signal (power level or voltage level) may be lower than the level of the bias signal supplied to the substrate support 11 during the process ST11 or process ST3.

The first processing gas includes a low-vapor-pressure material gas. The low-vapor-pressure material gas may be a carbon-containing gas. Examples of carbon-containing gas include at least one type of gas selected from a group consisting of C₃F₆ gas, C₄F₆ gas, C₄F₈ gas, Isopropyl alcohol (IPA) gas, C₃H₂F₄ gas, and C₄H₂F₆ gas. The low-vapor-pressure material gas may be a gas that exhibits vapor pressure at a temperature the same as or higher than the temperature indicated by the temperature-vapor pressure curve of C₄F₈.

The first processing gas may further include an inert gas. The inert gas may be, for example, a rare gas such as Ar gas, He gas, or Kr gas, or nitrogen gas. In the first processing gas, the flow rate ratio of the inert gas to the low-vapor-pressure material gas may be, for example, less than 50% by volume.

In the process ST2, the pressure within the plasma processing space 10s may be higher than the pressure in the plasma processing space 10s during the process ST11 or process ST3. The pressure may be, for example, 50 mT (6.7 Pa) or higher; in one example, the pressure may be 50 mT (6.7 Pa), 100 mT (13.3 Pa), 200 mT (26.6 Pa), or 400 mT (53.3 Pa). The pressure may also be set to a value below the vapor pressure indicated by the vapor pressure curve of the low-vapor-pressure material gas included in the first processing gas. Also, in the process

ST2, the substrate support 11 may be set to a temperature of 0° C. or lower. For example, the set temperature may be −20° C., −30° C., −40° C., or −50° C.

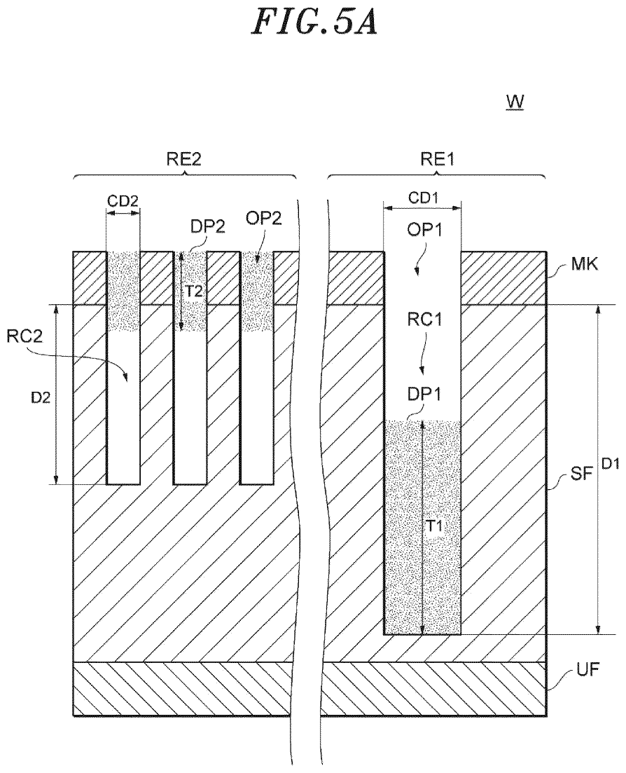

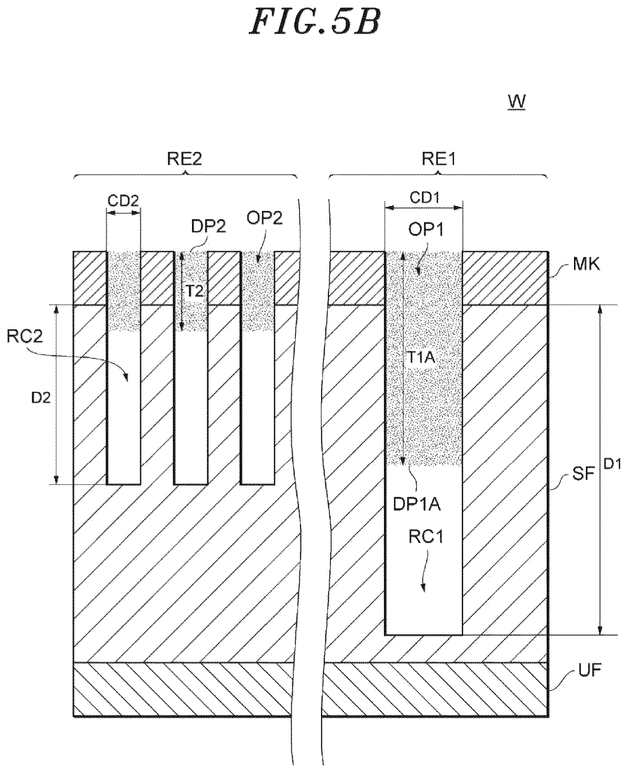

FIG. 5A illustrates an example of a cross-sectional structure of substrate W after processing of the process ST2. As shown in FIG. 5A, a deposition film DP1 is formed in the first recess RC1 by processing of the process ST2. The deposition film DP1 is a film originating from the low-vapor-pressure material gas included in the first processing gas. The low-vapor-pressure material in the plasma generated during the process ST2 may be fluidity. During the processing of the process ST2, the deposition film DP1 may be deposited in the recess RC1 in a bottom-up manner from the bottom of the recess RC1 to the top (in the direction from the bottom to the top in FIG. 5A). The deposition film DP1 may be formed in a portion of the recess RC1 or formed to fill the entire recess RC1. The deposition film DP1 may be formed in a portion or the entire opening OP1.

During the processing of the process ST2, a deposition film may be formed on opening OP2 and/or the second recess RC2. FIG. 5A illustrates an example where the deposition film DP2 is formed over the entirety of opening OP2 and a portion of the upper region of the second recess RC2. During the processing of the process ST2, the deposition film DP2 may be deposited onto opening OP2 and recess RC2 in a top-down manner from the top of opening OP2 downward (in the direction from top to bottom as shown in FIG. 5A). In the example shown in FIG. 5A, the lower deposition position of deposition film DP1 is located deeper than that of deposition film DP2.

As shown in FIG. 5A, the thickness T1 of the deposition film DP1 (dimension from the top to the bottom of DP1) is greater than the thickness T2 of the deposition film DP2 (dimension from the top to the bottom of DP2). The difference in the thickness may be thought to result from the fact that the opening dimension CD1 of opening OP1 is larger than the opening dimension CD2 of opening OP2. In other words, the larger opening OP1 allows more low-vapor-pressure material from the plasma to flow in. On the other hand, the smaller opening OP2 makes it more difficult for the low-vapor-pressure material from the plasma to flow in, which may suppress the formation of the deposition film.

FIG. 5B illustrates another example of the cross-sectional structure of substrate W after processing of the process ST2. FIG. 5B shows an example in which a deposition film is formed in a top-down manner even for opening OP1 and the first recess RC1. As shown in FIG. 5B, the deposition film DP1A is formed over the entire area of opening OP1 and a portion of the upper side of the first recess RC1. The deposition film DP2 employs the same configuration as described in the example shown in FIG. 5A. In this example, the thickness T1A of deposition film DP1A (dimension from the top to the bottom of DP1A) is greater than the thickness T2 of deposition film DP2 (dimension from the top to the bottom of DP2). Furthermore, the lower part of the deposition film DP1A is located at a position deeper than the lower deposition position of the deposition film DP2.

The fluidity of the low-vapor-pressure material in the plasma generated in the process ST2 may be appropriately adjusted by altering factors such as the type of material, the pressure within the plasma processing space 10s, and the set temperature of the substrate support 11. Through the adjustment, the deposition pattern of the deposition films DP1 and DP2 (e.g., deposition location or direction) may be modified. For example, in both the first recess RC1 and the second recess RC2, the deposition film may be formed in a bottom-up manner starting from the bottom of the recess. In this case, the height of the deposition film formed in the first recess RC1 is greater than the height of the deposition film formed in the second recess RC2.

### (Process ST3: Etching Substrate)

In the process ST3, the silicon-containing film SF in the first recess RC1 and the second recess RC2 is etched using plasma generated from the second processing gas. First, the second processing gas is supplied to the plasma processing space 10s from the gas supply 20. During the processing of the process ST3, the type of gas or the flow rate (partial pressure) of the gas included in the second processing gas may or may not be altered. For example, if the silicon-containing film SF is composed of a multilayer film made of different types of silicon-containing films, the composition of the processing gas or the flow rate (partial pressure) of each gas may be adjusted as the etching progresses (i.e., depending on the type of film being etched).

During the process ST3, the temperature of the substrate support 11 may be maintained at the set temperature adjusted in the process ST11. Also, the set temperature of the substrate support 11 may be changed depending on the type of processing gas or silicon-containing film. For example, when the processing gas includes a fluorine-containing gas (e.g., hydrogen fluoride gas), the set temperature of the substrate support 11 may be 0° C. or lower. In the process ST3, the pressure in the plasma processing space 10s may be lower than the pressure in the plasma processing space 10s during the process ST2. The pressure, for example, may be less than 50 mT (6.7 Pa).

Next, a source RF signal is supplied to the lower electrode of the substrate support 11 and/or the upper electrode of the showerhead 13. This creates a high-frequency electric field between the showerhead 13 and the substrate support 11, generating plasma from the processing gas within the plasma processing space 10s. Also, a bias signal is supplied to the lower electrode of the substrate support 11, creating a bias potential between the plasma and the substrate W. Due to the bias potential, reactive species in the plasma, such as ions and radicals, are drawn toward the substrate W. As a result, the silicon-containing film SF in the first recess RC1 and the second recess RC2 is etched.

In the process ST12, the bias signal may be a bias RF signal supplied from the second RF generator 31b. Also, the bias signal may be a bias DC signal supplied from the DC generator 32a. Both the source RF signal and the bias signal may be continuous waves or pulsed waves, or one may be a continuous wave while the other is a pulsed wave. If both the source RF signal and the bias signal are pulsed waves, the periods of the pulsed waves may or may not be synchronized. The duty ratio of the source RF signal and/or bias signal may be set appropriately; for example, the duty ratio may range from 1% to 80% or 5% to 50%. Also, if the bias DC signal is used as the bias signal, the pulsed wave may have a waveform such as rectangular, trapezoidal, triangular, or a combination of the aforementioned waves. The polarity of the bias DC signal may be negative or positive, depending on the potential set for the substrate W to create a potential difference between the plasma and the substrate for attracting ions.

In the process ST3, the supply and cessation of at least one of the source RF signal and the bias signal may be repeated in an alternate fashion. For example, while the source RF signal is supplied continuously, the supply and cessation of the bias signal may be repeated alternately. Alternatively, while the supply and cessation of the source RF signal is repeated alternately, the bias signal may be supplied continuously. Furthermore, the supply and cessation of both the source RF signal and the bias signal may be repeated alternately.

The second processing gas may be selected such that the silicon-containing film SF may be etched with a sufficiently high selectivity relative to the mask MK. For example, the second processing gas may include a gas capable of generating hydrogen fluoride species (HF species) in the plasma. The HF species includes at least one of hydrogen fluoride gas, radicals, and ions.

The gas capable of generating HF species may, for example, be hydrogen fluoride gas (HF gas) and/or hydrofluorocarbon gas. The hydrofluorocarbon gas may contain 2 or more, 3 or more, or 4 or more carbon atoms. The hydrofluorocarbon gas may include, for example, at least one selected from a group consisting of CH₂F₂ gas, C₃H₂F₄ gas, C₃H₂F₆ gas, C₃H₃F₅ gas, C₄H₂F₆ gas, C₄H₅F₅ gas, C₄H₂F₈ gas, C₅H₂F₆ gas, C₅H₂F₁₀ gas, and C₅H₃F₇ gas. In one example, the hydrofluorocarbon gas includes at least one selected from a group consisting of CH₂F₂ gas, C₃H₂F₄ gas, C₃H₂F₆ gas, and C₄H₂F₆ gas.

The gas capable of generating HF species may, for example, be a mixed gas containing a hydrogen source and a fluorine source. The hydrogen source may include at least one selected from a group consisting of H₂ gas, NH₃ gas, H₂O gas, H₂O₂ gas, and hydrocarbon gases (e.g., CH₄ gas, C₃H₆ gas). The fluorine source may include fluorine-containing gases that do not contain carbon, such as NF₃ gas, SF₆ gas, WF₆ gas, or XeF₂ gas. Also, the fluorine source may include fluorine-containing gases that contain carbon, such as fluorocarbon gases and hydrofluorocarbon gases. The fluorocarbon gases may include, for example, at least one selected from a group consisting of CF₄ gas, C₂F₂ gas, C₂F₄ gas, C₃F₆ gas, C₃F₈ gas, C₄F₆ gas, C₄F₈ gas, and C F₈ gas. The hydrofluorocarbon gases may include, for example, at least one selected from a group consisting of CHF₃ gas, CH₂F₂ gas, CH₃F gas, C₂HF₅ gas, and hydrofluorocarbon gases containing three or more carbon atoms (e.g., C₃H₂F₄ gas, C₃H₂F₆ gas, C₄H₂F₆ gas).

The gas capable of generating HF species included in the second processing gas (all gases excluding any inert gas if the second processing gas contains the inert gas) may have the highest flow rate (partial pressure) among all gases in the second processing gas. For example, the flow rate of the gas capable of generating HF species may account for 50 volume % or more, 60 volume % or more, 70 volume % or more, 80 volume % or more, 90 volume % or more, or 95 volume % or more of the total flow rate of the second processing gas (the flow rate of all gases excluding any inert gas if the second processing gas contains the inert gas). The flow rate of the gas capable of generating HF species may be less than 100 volume %, 99.5 volume % or less, 98 volume % or less, or 96 volume % or less of the total flow rate of the second processing gas. For example, the flow rate of the gas capable of generating HF species may be adjusted to range from 70 volume % to 96 volume % of the total flow rate of the second processing gas.

The second processing gas may further include a phosphorus-containing gas. A phosphorus-containing gas includes phosphorus-containing molecules. The phosphorus-containing molecules may be oxides such as tetraphosphorus decaoxide P₄O₁₀, tetraphosphorus octaoxide P₄O₈, or tetraphosphorus hexaoxide P₄O₆. Tetraphosphorus decaoxide is sometimes referred to as diphosphorus pentoxide P₂O₅. Phosphorus-containing molecules may also include halides (phosphorus halides) such as phosphorus trifluoride PF₃, phosphorus pentafluoride PF₅, phosphorus trichloride PCl₃, phosphorus pentachloride PCl₅, phosphorus tribromide PBr₃, phosphorus pentabromide PBr₅, and phosphorus triiodide PI₃. In other words, the phosphorus-containing molecules may include fluorine as a halogen element, such as phosphorus fluorides. Alternatively, the phosphorus-containing molecules may include halogen elements other than fluorine. Phosphorus-containing molecules may also include phosphoryl halides such as phosphoryl fluoride POF₃, phosphoryl chloride POCl₃, and phosphoryl bromide POBr₃. Other examples of phosphorus-containing molecules include phosphine PH₃, calcium phosphide Ca₃P₂, phosphoric acid H₃PO₄, sodium phosphate Na₃PO₄, and hexafluorophosphoric acid HPF₆. The phosphorus-containing molecules may also include fluoro-phosphines H_{g}PFₕ. Here, the sum of g and h is 3 or 5. Examples of fluoro-phosphines include HPF₂ and H₂PF₃. The processing gas may contain, as at least one phosphorus-containing molecule, at least one or more phosphorus-containing molecules from the above list of phosphorus-containing molecules. For example, the second processing gas may include, as at least one phosphorus-containing molecule, at least one from PF₃, PCl₃, PF₅, PCl₅, POCl₃, PH₃, PBr₃, or PBr₅. Furthermore, if the phosphorus-containing molecules in the processing gas are in liquid or solid form, the phosphorus-containing molecules may be vaporized, for example, by heating, and then supplied to the plasma processing space 10s.

The phosphorus-containing gas may be a PClₐF_{b} gas (where a is an integer equal to or greater than 1, b is an integer equal to or greater than 0, and a+b is an integer equal to or less than 5) or a PC_{c}H_{d}Fₑ gas (where d and e are integers each ranging from 1 to 5, and c is an integer ranging from 0 to 9).

The PClₐF_{b} gas may include, for example, at least one type of gas selected from a group consisting of PClF_{b} gas, PCl₂F gas, and PCl₂F₃ gas.

The PC_{c}H_{d}Fₑ gas may include, for example, at least one type of gas selected from a group consisting of PF₂CH₃ gas, PF(CH₃)₂ gas, PH₂CF₃ gas, PH(CF₃)₂ gas, PCH₃(CF₃)₂ gas, PH₂F gas, and PF₃ (CH₃)₂ gas.

The phosphorus-containing gas may be a PCl_{c}F_{d}CₑH_{f} gas (where c, d, e, and f are integers greater than or equal to 1). Also, the phosphorus-containing gas may include gases with a molecular structure containing phosphorus (P), fluorine (F), and halogens other than fluorine (e.g., CI, Br, or I); gases with a molecular structure containing phosphorus (P), fluorine (F), carbon (C), and hydrogen (H); or gases with a molecular structure containing phosphorus (P), fluorine (F), and hydrogen (H).

The phosphorus-containing gas may also utilize phosphine-based gases. Examples of phosphine-based gases include phosphine (PH₃), compounds in which at least one hydrogen atom in phosphine is substituted with a suitable substituent, and phosphinic acid derivatives.

Substituents for replacing hydrogen atoms in phosphine are not particularly limited to specific types and may include, for example, halogen atoms such as fluorine or chlorine; alkyl groups such as methyl, ethyl, or propyl; and hydroxyalkyl groups such as hydroxymethyl, hydroxyethyl, or hydroxypropyl; an example includes chlorine atoms, methyl groups, and hydroxymethyl groups.

Examples of phosphonic acid derivatives include phosphonic acid H₃O₂P, alkylphosphonic acid PHO(OH)R, and dialkylphosphonic acid PO(OH)R₂.

Phosphine-based gases may include, for example, at least one type of gas selected from a group consisting of dichloro(methyl)phosphine gas PCH₃Cl₂, chloro(dimethyl)phosphine) gas P(CH₃)₂Cl, dichloro(hydroxymethyl)phosphine gas P(HOCH₂)Cl₂, chloro(dihydroxymethyl)phosphine gas P(HOCH₂)₂Cl, dimethyl(hydroxymethyl)phosphine gas P(HOCH₂)(CH₃)₂, methyl(dihydroxymethyl)phosphine gas P(HOCH₂)₂(CH₃), tris(hydroxymethyl)phosphine gas P(HOCH₂)₃, phosphonic acid gas H₃O₂P, methylphosphonic acid gas PHO(OH)(CH₃), and dimethylphosphonic acid gas PO(OH)(CH₃)₂.

The flow rate of the phosphorus-containing gas included in the second processing gas may be 20 volume % or less, 10 volume % or less, or 5 volume % or less of the total flow rate of the second processing gas.

The second processing gas may further include a tungsten-containing gas. The tungsten-containing gas may be a gas containing tungsten and halogen; in one example, the tungsten-containing gas may be WFₓCl_{y} gas (where x and y are integers between 0 and 6, inclusive, and the sum of x and y is between 2 and 6, inclusive). Specifically, examples of tungsten-containing gases include tungsten and fluorine-containing gases such as tungsten difluoride WF₂ gas, tungsten tetrafluoride WF₄ gas, tungsten pentafluoride WF₅ gas, and tungsten hexafluoride WF₆ gas; and tungsten and chlorine-containing gases such as tungsten dichloride WClk₂ gas, tungsten tetrachloride WCl₄ gas, tungsten pentachloride WCl₅ gas, and tungsten hexachloride WCl₆ gas. Among these, at least one of WF₆ gas or WCl₆ gas may be used as the tungsten-containing gas. The flow rate of the tungsten-containing gas may be 5 volume % or less of the total flow rate of the second processing gas. Furthermore, the second processing gas may include titanium-containing gas or molybdenum-containing gas instead of or in addition to the tungsten-containing gas.

The second processing gas may further include a carbon-containing gas. The carbon-containing gas may be, for example, one or both of a fluorocarbon gas and a hydrofluorocarbon gas. In one example, the fluorocarbon gas may include at least one type of gas selected from a group consisting of CF₄, C₂F₂, C₂F₄, C₃F₆, C₃F₈, C₄F₆, C₄F₈, and C₅F₈ gas. In one example, the hydrofluorocarbon gas may include at least one type of gas selected from a group consisting of CHF₃, CH₂F₂, CH₃F, C₂HF₅, C₂H₂F₄, C₂H₃F₃, C₂H₄F₂, C₃HF₇, C₃H₂F₂, C₃H₂F₄, C₃H₂F₆, C₃H₃F₅, C₄H₂F₆, C₄H₅F₅, C₄H₂F₈, C₅H₂F₆, C₅H₂F₁₀, and C₅H₃F₇ gas. Also, the carbon-containing gas may be a straight-chain gas with unsaturated bonds. Examples of straight-chain carbon-containing gases with unsaturated bonds include at least one type of gas selected from a group consisting of C₃F₆ (hexafluoropropene), C₄F₈ (octafluoro-1-butene, octafluoro-2-butene), C₃H₂F₄ (1,3,3,3-tetrafluoropropene), C₄H₂F₆ (trans-1,1,1,4,4,4-hexafluoro-2-butene), C₄F₈O (pentafluoroethyl trifluorovinyl ether), CF₃COF (1,2,2,2-tetrafluoroethan-1-one), CHF₂COF (difluoroacetic acid fluoride), and COF₂ (carbonyl fluoride) gas.

The second processing gas may further include an oxygen-containing gas. The oxygen-containing gas may include at least one type of gas selected from a group consisting of O₂, CO, CO₂, H₂O, and H₂O₂. In one example, the oxygen-containing gas may include at least one type of gas selected from a group consisting of oxygen-containing gases other than H₂O, such as O₂, CO, CO₂, and H₂O₂. The flow rate of the oxygen-containing gas may be adjusted based on the flow rate of the carbon-containing gas.

The second processing gas may further include halogen-containing gases excluding fluorine. The halogen-containing gases excluding fluorine may include chlorine-containing gases, bromine-containing gases, and/or iodine-containing gases. The chlorine-containing gases may include, for example, at least one type of gas selected from a group consisting of Cl₂, SiCl₂, SiCl₄, CCl₄, SiH₂Cl₂, Si₂Cl₆, CHCl₃, SO₂Cl₂, BCl₃, PCl₃, PCl₅, and POCl₃. The bromine-containing gases may include, for example, at least one type of gas selected from a group consisting of Br₂, HBr, CBr₂F₂, C₂F₅Br, PBr₃, PBr₅, POBr₃, and BBr₃. The iodine-containing gases may include, for example, at least one type of gas selected from a group consisting of HI, CF₃I, C₂F₅I, C₃F₂I, IF₅, IF₇, I₂, and PI₃. In one example, the halogen-containing gas excluding fluorine may include at least one type of gas selected from a group consisting of Cl₂ gas, Br₂ gas, and HBr gas. In another example, the halogen-containing gas excluding fluorine may be Cl₂ gas or HBr gas.

The second processing gas may further include inert gases. The inert gases may include, for example, rare gases such as Ar gas, He gas, or Kr gas, or nitrogen gas.

During the etching performed in the process ST13, the silicon-containing film SF in the first recess RC1 and the second recess RC2 is etched in the depth direction along with deposition films (DP1/DP1A, DP2, and so on) based on the shape of the openings OP1 and OP2 in the mask MK. The incidence frequency of reactive species in the plasma on the first recess RC1 may be higher than that on the second recess RC2. The higher incidence frequency results from the larger opening dimension CD1 of the mask MK in region RE1 compared to the opening dimension CD2 in region RE2. Here, the deposition film DP1 (DP1A) is formed on the first recess RC1, and etching of the deposition film DP1 (DP1A) occurs. Consequently, the etching of the silicon-containing film SF in the first recess RC1 along the depth direction is suppressed compared to the etching performed in the second recess RC2. Even when the deposition film DP2 is formed in the second recess RC2, the thickness T1 (T1A) of the deposition film DP1 (DP1A) in the first recess RC1 is greater than the thickness T2 of the deposition film DP2. Therefore, similarly, the etching of the silicon-containing film SF in the first recess RC1 along the depth direction is suppressed compared to the etching performed in the second recess RC2. In other words, during the etching in the process ST3, the etching rate of the first recess RC1 is suppressed to be lower than or approximately equal to the etching rate of the second recess RC2.

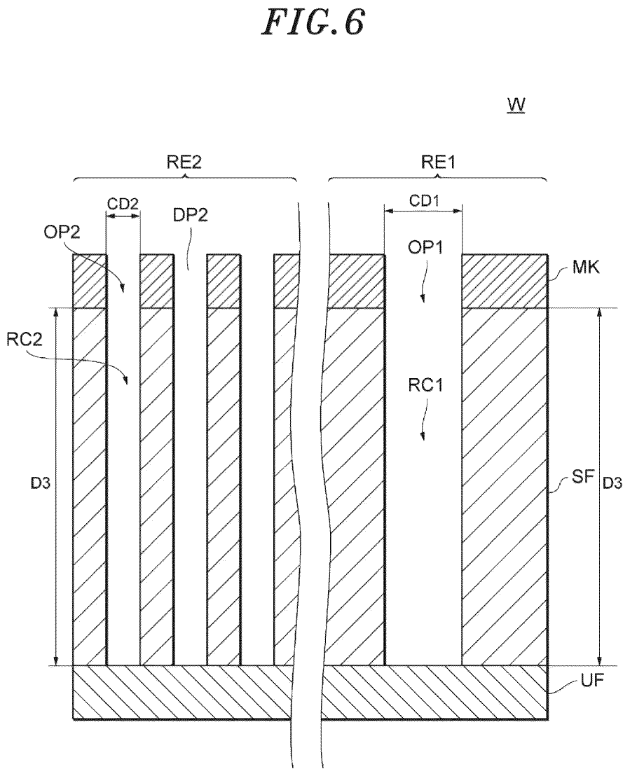

FIG. 6 illustrates an example of the cross-sectional structure of the substrate W after processing of the process ST3. As shown in FIG. 6, the processing of the process ST3 causes the first recess RC1 and the second recess RC2 to be etched in the depth direction, making the bottoms of both recesses almost simultaneously reach the base film UF. In other words, when the etching terminates, the depths D3 of the recesses in the first region RE1 and the second region RE2 become identical.

According to the present processing method, by forming a deposition film during the process ST2, the etching rate of the first recess RC1 in the process ST3 is suppressed to a level lower than or equal to the etching rate of the second recess RC2. This improves the uniformity of the etching rates of the silicon-containing film SF in the first region RE1 and the second region RE2. Therefore, even when achieving a selectivity ratio for the base film UF is challenging, making it difficult to stop etching using the base film UF, the present processing method enables the silicon-containing film SF in both the first region RE1 and the second region RE2 to be etched simultaneously down to the base film UF.

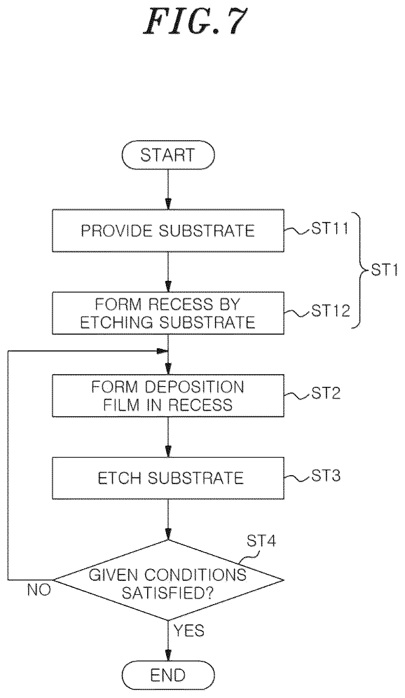

FIG. 7 is a flowchart illustrating another example of the present processing method. As shown in FIG. 7, the present example determines whether predetermined conditions are satisfied after the process ST3 and repeats the processes ST2 and ST3 until the conditions are met. Apart from the above processing step, the flowchart of the present example is identical to the flowchart shown in FIG. 2.

In the process ST4, the predetermined conditions may be appropriately defined. For instance, the predetermined condition may relate to the number of cycles in which the processes ST2 and ST3 are performed in one cycle. In other words, the method may determine whether the number of cycles reaches a predetermined repetition count (e.g., 10, 20, 30, or 50) and repeat the processes ST2 and ST3 until the specified number is reached. Also, the repetition count may be determined based on the film thickness of the silicon-containing film SF (i.e., the depth to be etched).

For example, the predetermined condition may relate to the dimensions of the first recess RC1 and/or the second recess RC2 after processing of the process ST3. In other words, after the process ST3, the method may determine whether the depth or bottom width of the first recess RC1 and/or the second recess RC2 reaches a given value or falls within a specified range and repeat cycles of the processes ST2 and ST3 until the depth or bottom width reaches the given value or falls within the specified range. The dimensions of the first recess RC1 and/or the second recess RC2 may be measured using an optical measurement device. Also, when the present processing method processes a plurality of substrates W as a single unit (hereinafter referred to as a “lot”), whether to repeat the cycles may be determined based on the dimensions of the processed first recess RC1 and/or second recess RC2 only for one or a few substrates W included in the lot. In this case, the number of repeated cycles may be recorded and used as the predetermined condition for other substrates included in the same lot. In other words, for the other substrates, the method may determine whether the recorded number of cycles has been reached, and if not, repeat the processes ST2 and ST3.

### Embodiment

Next, an embodiment of the present disclosure will be described. It should be noted that the present disclosure is not limited by the following embodiment at all.

Using the plasma processing system shown in FIG. 1, a substrate with the same structure as the substrate W illustrated in FIG. 3 was etched according to the flowchart described in FIG. 2. An amorphous carbon film was used as the mask MK. The mask MK was designed with a large-diameter pattern region (first region RE1) and a small-diameter pattern region (second region RE2). The opening dimension CD1 of the opening OP1 formed in the large-diameter pattern region was 200-400 nm. The opening dimension CD2 of the opening OP2 formed in the small-diameter pattern region was 80 nm. A silicon oxide film was used as the silicon-containing film SF.

In the process ST12, a processing gas containing HF gas, phosphorus-containing gas, hydrofluorocarbon-containing gas, and oxygen-containing gas were used. Plasma was generated by supplying a source RF signal and a bias RF signal, and the silicon-containing film SF was etched. The temperature of the substrate support 11 was set to −70° C. The pressure in the plasma processing space 10s was set at 30 mT (4.0 Pa). After the completion of process ST12, a first recess RC1 was formed in the large-diameter pattern region, and a second recess RC2 was formed in the small-diameter pattern region. The depth of the first recess RC1 was 4099 nm, and the depth of the second recess RC2 was 1855 nm.

In the process ST2, a first processing gas containing C₄F₆ gas was used. Plasma was generated by supplying only the source RF signal without supplying the bias signal, and a deposition film was formed in the first recess RC1 and the second recess RC2. The temperature of the substrate support 11 was set to −70° C. The pressure in the plasma processing space 10s was set at 400 mT (53.3 Pa). After the completion of process ST2, a bottom-up deposition film was formed in the opening OP1 and the first recess RC1. The deposition height of the film was 6730 nm. In the opening OP2 and the second recess RC2, a top-down deposition film was formed. The height of the deposition film formed in the second recess RC2 was 650 nm.

In the process ST3, a second processing gas containing HF gas, phosphorus-containing gas, hydrofluorocarbon-containing gas, and oxygen-containing gas were used. Plasma was generated by supplying both the source RF signal and the bias RF signal, further etching the first recess RC1 and the second recess RC2. The temperature of the substrate support 11 was set to −70° C. The pressure in the plasma processing space 10s was set at 30 mT (4.0 Pa). After the completion of process ST3, the depth of the first recess RC1 was 4264 nm, and the depth of the second recess RC2 was 4196 nm. In other words, at the end of the etching process, the depths of the recesses formed in the silicon-containing film SF were almost identical in the large-diameter pattern region and the small-diameter pattern region.

The embodiments described above are provided for illustrative purposes and are not intended to limit the scope of the present disclosure. Various modifications may be made without departing from the scope and spirit of the present disclosure. For example, the etching methods according to each embodiment may be performed using plasma processing apparatus employing an arbitrary plasma source, such as inductively coupled plasma or microwave plasma, in addition to the capacitively coupled plasma processing apparatus 1.

The embodiments of the present disclosure may further include the following aspects.

### APPENDIX 1

An etching method performed in a plasma processing apparatus having a chamber, the method comprising:
(a) preparing a substrate on a substrate support within the chamber, wherein the substrate includes a silicon-containing film having a first recess and a second recess with a smaller opening dimension than the first recess, and a mask provided on the silicon-containing film, the mask having openings that expose the first recess and the second recess;
(b) forming a deposition film at least in the first recess using plasma generated from a first processing gas within the chamber, wherein the first processing gas includes at least one gas selected from a group consisting of C₃F₆ gas, C₄F₆ gas, C₄F₈ gas, isopropyl alcohol (IPA) gas, C₃H₂F₄ gas, and C₄H₂F₆ gas; and
(c) etching the silicon-containing film in the first recess and the second recess using plasma generated from a second processing gas within the chamber; wherein, in process (b), the temperature of the substrate support is set to 0° C. or lower, and the pressure within the chamber is higher than the pressure within the chamber in process (c).

### APPENDIX 2

An etching method performed by a plasma processing apparatus having a chamber, the method comprising the processes of:
(a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess;
(b) forming a deposition film on at least the first recess using plasma generated from a first processing gas within the chamber, wherein the first processing gas exhibits vapor pressure at a temperature the same as or higher than the temperature indicated by the temperature-vapor pressure curve of C₄F₈; and
(c) etching the silicon-containing film in the first recess and the second recess using plasma generated from a second processing gas within the chamber, wherein, during process (b), a temperature of the substrate support is set to 0° C. or lower, and a pressure within the chamber is higher than a pressure within the chamber during process (c).

### APPENDIX 3

The method of Appendix 1 or 2, wherein the depth of the first recess in the substrate prepared in process (a) is greater than the depth of the second recess.

### APPENDIX 4

The method of any one of Appendices 1 to 3, wherein, in process (b), the deposition film is formed at least on the bottom of the first recess.

### APPENDIX 5

The method of any one of Appendices 1 to 4, wherein, in process (b), the deposition film is formed on the first recess and the second recess, and when process (b) is terminated, the thickness of the deposition film formed in the first recess, measured from a top to a bottom, is thicker than the thickness of the deposition film formed on the second recess, measured from a top to a bottom.

### APPENDIX 6

The method of any one of Appendices 1 to 5, wherein, when process (b) is terminated, a lower part of the deposition film formed in the first recess is located at a position deeper than that of a lower part of the deposition film formed in the second recess.

### APPENDIX 7

The method of any one of Appendices 1 to 6, wherein process (b) and process (c) are alternately repeated.

### APPENDIX 8

The method of any one of Appendices 1 to 7, wherein process (b) and process (c) are performed within the same chamber.

### APPENDIX 9

The method of any one of Appendices 1 to 8, wherein, in process (b), the pressure within the chamber is 50 mT (6.7 Pa) or more.

### APPENDIX 10

The method of any one of Appendices 1 to 9, wherein, in process (b), no bias signal is supplied to the substrate support, or a bias signal is supplied at a lower level than the bias signal in process (c).

### APPENDIX 11

The method of any one of Appendices 1 to 10, wherein the second processing gas includes a fluorine-containing gas.

### APPENDIX 12

The method of Appendix 11, wherein the fluorine-containing gas includes at least one of hydrogen fluoride gas and hydrofluorocarbon gas.

### APPENDIX 13

The method of Appendix 12, wherein, in process (c), temperature of the substrate support is set to 0° C. or lower.

### APPENDIX 14

The method of any one of Appendices 11 to 13, wherein the second processing gas further includes at least one of a phosphorus-containing gas and a carbon-containing gas.

### APPENDIX 15

The method of any one of Appendices 11 to 14, wherein the second processing gas further includes at least one gas selected from a group consisting of a tungsten-containing gas, a halogen-containing gas other than fluorine, an oxygen-containing gas, and an inert gas.

### APPENDIX 16

The method of any one of Appendices 1 to 15, wherein, in process (c), plasma generated from the second processing gas includes at least one of HF species, phosphorus-containing species, and carbon-containing species

### APPENDIX 17

The method of any one of Appendices 1 to 16, wherein process (a) includes a step of forming the first recess and the second recess by etching using plasma generated from the second processing gas.

### APPENDIX 18

The method of any one of Appendices 1 to 17, wherein the silicon-containing film is a laminated film that includes a silicon oxide film, a silicon nitride film, a silicon oxynitride film, a silicon carbonitride film, a polysilicon film, a carbon-containing silicon film, or a combination of two or more of the above

### APPENDIX 19

The method of any one of Appendices 1 to 18, wherein the mask includes at least one of carbon, tungsten, titanium, and molybdenum.

### APPENDIX 20

A plasma processing system equipped with a plasma processing apparatus with a chamber and a controller, wherein the controller is configured to perform controlling of:
(a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess;
(b) forming a deposition film on at least the first recess using plasma generated from a first processing gas within the chamber, wherein the first processing gas includes at least one gas selected from a group consisting of C₃F₆ gas, C₄F₆ gas, C₄F₈ gas, isopropyl alcohol (IPA) gas, C₃H₂F₄ gas, and C₄H₂F₆ gas; and
(c) etching the silicon-containing film in the first recess and the second recess using plasma generated from a second processing gas within the chamber,
wherein the temperature of the substrate support is set to 0° C. or lower in the controlling of (b), while the pressure within the chamber is higher than the pressure within the chamber in the controlling of (c).

### APPENDIX 21

A plasma processing system equipped with a plasma processing apparatus with a chamber and a controller, wherein the controller is configured to perform controlling of:
(a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess;
(b) forming a deposition film on at least the first recess using plasma generated from a first processing gas within the chamber, wherein the first processing gas exhibits vapor pressure at a temperature the same as or higher than the temperature indicated by the temperature-vapor pressure curve of C₄F₈; and
(c) etching the silicon-containing film in the first recess and the second recess using plasma generated from a second processing gas within the chamber,
wherein the temperature of the substrate support is set to 0° C. or lower in the controlling of (b), while the pressure within the chamber is higher than the pressure within the chamber in the controlling of (c).

### APPENDIX 22

A method for producing a device in a plasma processing apparatus with a chamber, the method comprising:
(a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess;
(b) forming a deposition film on at least the first recess using plasma generated from a first processing gas within the chamber, wherein the first processing gas includes at least one gas selected from a group consisting of C₃F₆ gas, C₄F₆ gas, C₄F₈ gas, isopropyl alcohol (IPA) gas, C₃H₂F₄ gas, and C₄H₂F₆ gas; and
(c) etching the silicon-containing film in the first recess and the second recess using plasma generated from a second processing gas within the chamber,
wherein, during process (b), a temperature of the substrate support is set to 0° C. or lower, and a pressure within the chamber is higher than a pressure within the chamber during process (c).

### APPENDIX 23

A method for producing a device in a plasma processing apparatus with a chamber, the method comprising:
(a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess;
(b) forming a deposition film on at least the first recess using plasma generated from a first processing gas within the chamber, wherein the first processing gas exhibits vapor pressure at a temperature the same as or higher than the temperature indicated by the temperature-vapor pressure curve of C₄F₈; and
(c) etching the silicon-containing film in the first recess and the second recess using plasma generated from a second processing gas within the chamber,
wherein, during process (b), a temperature of the substrate support is set to 0° C. or lower, and a pressure within the chamber is higher than a pressure within the chamber during process (c).

### APPENDIX 24

A program for causing a computer of a plasma processing system equipped with a plasma processing apparatus with a chamber and a controller to perform controlling of:
(a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess;
(b) forming a deposition film on at least the first recess using plasma generated from a first processing gas within the chamber, wherein the first processing gas includes at least one gas selected from a group consisting of C₃F₆ gas, C₄F₆ gas, C₄F₈ gas, isopropyl alcohol (IPA) gas, C₃H₂F₄ gas, and C₄H₂F₆ gas; and
(c) etching the silicon-containing film in the first recess and the second recess using plasma generated from a second processing gas within the chamber,
wherein the temperature of the substrate support is set to 0° C. or lower in the controlling of (b), while the pressure within the chamber is higher than the pressure within the chamber in the controlling of (c).

### APPENDIX 25

A program for causing a computer of a plasma processing system equipped with a plasma processing apparatus with a chamber and a controller to perform controlling of:
(a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess;
(b) forming a deposition film on at least the first recess using plasma generated from a first processing gas within the chamber, wherein the first processing gas exhibits vapor pressure at a temperature the same as or higher than the temperature indicated by the temperature-vapor pressure curve of C₄F₈; and
(c) etching the silicon-containing film in the first recess and the second recess using plasma generated from a second processing gas within the chamber,
wherein the temperature of the substrate support is set to 0° C. or lower in the controlling of (b), while the pressure within the chamber is higher than the pressure within the chamber in the controlling of (c).

### APPENDIX 26

A non-transitory computer readable medium storing the program of Appendix 24 or 25.

1. An etching method performed by a plasma processing apparatus having a chamber, the method comprising the processes of:
(a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess;
(b) forming a deposition film on at least the first recess using plasma generated from a first processing gas within the chamber, wherein the first processing gas includes at least one gas selected from a group consisting of C₃F₆ gas, C₄F₆ gas, C₄F₈ gas, Isopropyl alcohol (IPA) gas, C₃H₂F₄ gas, and C₄H₂F₆ gas; and
(c) etching the silicon-containing film in the first recess and the second recess using plasma generated from a second processing gas within the chamber,
wherein, during process (b), a temperature of the substrate support is set to 0° C. or lower, and a pressure within the chamber is higher than a pressure within the chamber during process (c).

2. An etching method performed by a plasma processing apparatus having a chamber, the method comprising the processes of:
(a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess;
(b) forming a deposition film on at least the first recess using plasma generated from a first processing gas within the chamber, wherein the first processing gas exhibits vapor pressure at a temperature the same as or higher than the temperature indicated by the temperature-vapor pressure curve of C₄F₈; and
(c) etching the silicon-containing film in the first recess and the second recess using plasma generated from a second processing gas within the chamber,
wherein, during process (b), a temperature of the substrate support is set to 0° C. or lower, and a pressure within the chamber is higher than a pressure within the chamber during process (c).

3. The method of claim 1, wherein the depth of the first recess in the substrate prepared in process (a) is greater than the depth of the second recess.

4. The method of claim 1, wherein, in process (b), the deposition film is formed at least on the bottom of the first recess.

5. The method of claim 1, wherein, in process (b), the deposition film is formed on the first recess and the second recess, and when process (b) is terminated, the thickness of the deposition film formed in the first recess, measured from a top to a bottom, is thicker than the thickness of the deposition film formed on the second recess, measured from a top to a bottom.

6. The method of claim 5, wherein, when process (b) is terminated, a lower part of the deposition film formed in the first recess is located at a position deeper than that of a lower part of the deposition film formed in the second recess.

7. The method of claim 1, wherein process (b) and process (c) are alternately repeated.

8. The method of claim 1, wherein process (b) and process (c) are performed within the same chamber.

9. The method of claim 1, wherein, in process (b), the pressure within the chamber is 50 mT (6.7 Pa) or more.

10. The method of claim 1, wherein, in process (b), no bias signal is supplied to the substrate support, or a bias signal is supplied at a lower level than the bias signal in process (c).

11. The method of claim 1, wherein the second processing gas includes a fluorine-containing gas.

12. The method of claim 11, wherein the fluorine-containing gas includes at least one of hydrogen fluoride gas and hydrofluorocarbon gas.

13. The method of claim 12, wherein, in process (c), temperature of the substrate support is set to 0° C. or lower.

14. The method of claim 11, wherein the second processing gas further includes at least one of a phosphorus-containing gas and a carbon-containing gas.

15. The method of claim 11, wherein the second processing gas further includes at least one gas selected from a group consisting of a tungsten-containing gas, a halogen-containing gas other than fluorine, an oxygen-containing gas, and an inert gas.

16. The method of claim 1, wherein, in process (c), plasma generated from the second processing gas includes at least one of HF species, phosphorus-containing species, and carbon-containing species.

17. The method of claim 1, wherein process (a) includes a step of forming the first recess and the second recess by etching using plasma generated from the second processing gas.

18. The method of claim 1, wherein the silicon-containing film is a laminated film that includes a silicon oxide film, a silicon nitride film, a silicon oxynitride film, a silicon carbonitride film, a polysilicon film, a carbon-containing silicon film, or a combination of two or more of the above.

19. The method of claim 1, wherein the mask includes at least one of carbon, tungsten, titanium, and molybdenum.

20. A plasma processing system equipped with a plasma processing apparatus with a chamber and a controller, wherein the controller is configured to perform controlling of:
(a) preparing a substrate on a substrate support within a chamber, where the substrate includes a silicon-containing film with a first recess and a second recess having a smaller opening dimension than the first recess and a mask formed on the silicon-containing film and with openings that expose the first recess and the second recess;
(b) forming a deposition film on at least the first recess using plasma generated from a first processing gas within the chamber, wherein the first processing gas includes at least one gas selected from a group consisting of C₃F₆ gas, C₄F₆ gas, C₄F₈ gas, isopropyl alcohol (IPA) gas, C₃H₂F₄ gas, and C₄H₂F₆ gas; and
(c) etching the silicon-containing film in the first recess and the second recess using plasma generated from a second processing gas within the chamber,
wherein the temperature of the substrate support is set to 0° C. or lower in the controlling of (b), while the pressure within the chamber is higher than the pressure within the chamber in the controlling of (c).
